(19) United States
(12) Patent Application Publication
(10) Pub. No.: US 2020/0043729 A1
(43) Pub. Date: Feb. 6, 2020

(54) LASER ANNEALING METHOD

(71) Applicant: SAKAI DISPLAY PRODUCTS CORPORATION, Osaka (JP)

(72) Inventors: Masakazu Tanaka, Osaka (JP); Shinji Koiwa, Osaka (JP); Kouichi Karatani, Osaka (JP); Akihiro Shinozuka, Osaka (JP); Nobutake Nodera, Osaka (JP); Takao Matsumoto, Osaka (JP)

(21) Appl. No.: 16/503,317

(22) Filed: Jul. 3, 2019

(30) Foreign Application Priority Data
Jul. 31, 2018 (JP) 2018-143165

(51) Int. Cl. H01L 21/02

(52) U.S. Cl. CPC H01L 21/02595; H01L 21/02532; H01L 21/02686

(57) ABSTRACT

A laser annealing method includes: step A of providing a substrate having an amorphous semiconductor film formed on a surface thereof; and step BF of selectively irradiating a portion of the amorphous semiconductor film with laser light. Step B includes a step of simultaneously forming, in said portion, a first melted region that is elongated in a first direction and a second direction that is elongated in a second melted region different from the first direction.

### BACKGROUND

### 1. Technical Field

The present invention relates to a laser annealing apparatus, a display panel, a laser annealing method and a mask.

### 2. Description of the Related Art

While examples of TFTs (Thin Film Transistors) of liquid crystal displays include amorphous silicon (non-crystalline, a-Si) TFTs and low temperature polysilicon (polycrystalline, p-Si) TFTs, for example, polycrystalline silicon has been often used instead of amorphous silicon in cases where there is a demand for high-speed operations such as with driver circuits, etc.

For crystallization of semiconductor film regions on the substrate, a process is known in the art for growing grain boundaries in the lateral direction parallel to the substrate surface by using a sequential lateral solidification (SLS) method. In the conventional SLS method, intended regions of a silicon film are irradiated with laser light through thin slit openings of a mask so as to completely melt the silicon of the regions, and the molten silicon is then re-solidified. When the molten silicon is re-solidified, grain boundaries grow in the direction of the thin width of the thin-slit irradiated regions corresponding to the openings. Then, by repeatedly shifting regions to be irradiated with laser light by shifting the substrate, it is possible to grow grain boundaries in the substrate shift direction (the scanning direction) (Patent Document No. 1: see Japanese National Phase PCT Laid-Open Publication No. 2000-505241).

### SUMMARY

However, with the conventional SLS method, the growth direction of grain boundaries is limited to the substrate scanning direction, and it is not possible to grow grain boundaries in an arbitrary direction.

The present invention has been made in view of the above, and an object thereof is to provide a laser annealing apparatus capable of producing grain boundaries in an intended direction, a display panel manufactured by the laser annealing apparatus, a laser annealing method, and a mask that is a part of the laser annealing apparatus.

A laser annealing apparatus according to an embodiment of the present invention is a laser annealing apparatus including a mask having an opening row, wherein the opening row includes openings each including an opening region and arranged in a scanning direction, for irradiating a substrate with laser light through the openings, wherein: a first opening including a first opening region and a second opening including a second opening region are arranged next to each other in a direction parallel to the scanning direction; and the mask has a first opening row in which the second opening region includes an opening region that is obtained by displacing a region corresponding to the first opening region at the second opening in a predetermined direction different from the scanning direction.

A display panel according to an embodiment of the present invention includes thin film transistors having active layers annealed by the laser annealing method according to an embodiment of the present invention.

A mask according to an embodiment of the present invention is a mask having an opening row, wherein the opening row includes openings each including an opening region and arranged in a scanning direction, wherein: a first opening including a first opening region and a second opening including a second opening region are arranged next to each other in a direction parallel to the scanning direction; and the mask has an opening row in which the second opening region includes an opening region that is obtained by displacing a region corresponding to the first opening region at the second opening in a predetermined direction different from the scanning direction.

A laser annealing method according to an embodiment of the present invention includes: step A of providing a substrate having an amorphous semiconductor film formed on a surface thereof; and step B of selectively irradiating a portion of the amorphous semiconductor film with laser light, wherein step B includes a step of simultaneously forming, in said portion, a first melted region that is elongated in a first direction and a second direction that is elongated in a second melted region different from the first direction.

According to the present invention, grain boundaries can be made to grow in intended directions, without being limited to the substrate scanning direction.

### BRIEF DESCRIPTION OF THE DRAWINGS

FIG. 1 is a schematic view showing an example configuration of a laser annealing apparatus of the present embodiment.

FIG. 2 is a schematic plan view showing an example configuration of a mask of the present embodiment.

FIG. 3 is a schematic view showing the positional relationship between openings and microlenses of the present embodiment.

FIG. 4A is a schematic view showing an example of a substrate scanning operation of the laser annealing apparatus of the present embodiment.

FIG. 4B is a schematic view showing an example of a substrate scanning operation of the laser annealing apparatus of the present embodiment.

FIG. 4C is a schematic view showing an example of a substrate scanning operation of the laser annealing apparatus of the present embodiment.

FIG. 5 is a schematic view showing a first example of openings of a mask portion of the present embodiment.

FIG. 6 is a schematic view showing an example of how an amorphous silicon film grows using a laser annealing apparatus of the present embodiment.

FIG. 7 is a schematic view showing a second example of openings of a mask portion of the present embodiment.

FIG. 8 is a schematic view showing an example of a display panel including thin film transistors that are annealed by a laser annealing apparatus of the present embodiment.

FIG. 9 is a schematic view showing another example of a display panel including thin film transistors that are annealed by a laser annealing apparatus of the present embodiment.

FIG. 10 is a schematic view showing a third example of openings of a mask portion of the present embodiment.

FIG. 11 is a schematic view showing an example of how grain boundaries grow in regions that are annealed by a mask portion shown in FIG. 10.

FIG. 12 is a schematic view showing a fourth example of openings of a mask portion of the present embodiment.

FIG. 13 is a schematic view showing an example of how grain boundaries grow in regions that are annealed by a mask portion shown in FIG. 12.

FIG. 14 is a flow chart showing an example of a laser annealing method using the laser annealing apparatus of the present embodiment.

### DETAILED DESCRIPTION

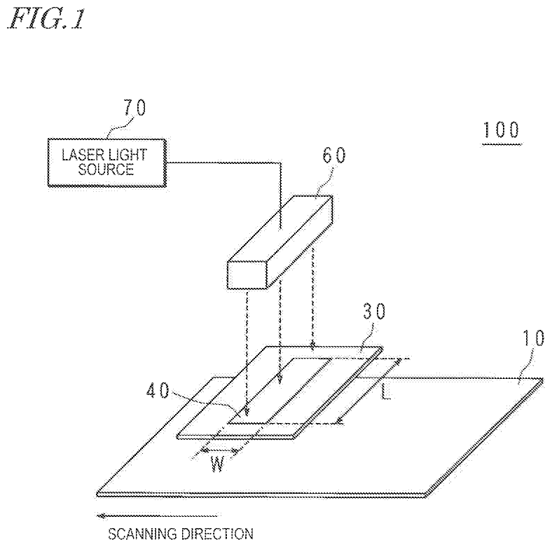

The present invention will now be described with reference to drawings that show embodiments thereof. FIG. 1 is a schematic view showing an example configuration of a laser annealing apparatus of the present embodiment. A laser annealing apparatus 100 of the present embodiment includes a laser light source 70 that emits laser light, an optical system 60 that includes a group of lenses for shaping the laser light emitted from the laser light source 70 into a parallel beam, a mask (light-blocking plate) 30 that includes a mask portion 40 where openings and microlenses to be described below are arranged in an array, etc. The parallel beam shaped through the optical system 60 selectively irradiates intended locations of a substrate 10 through the openings and the microlenses of the mask portion 40. The substrate 10 is transferred at a constant speed by a driving mechanism (not shown). The laser light source 70 shoots laser light at time intervals such that laser light is shot each time an irradiation position of the substrate 10 arrives at a position corresponding to an opening. Note that the laser annealing apparatus 100 may be configured so that the mask 30, or the like, is moved while the substrate 10 is fixed, instead of moving the substrate 10. An example where the substrate 10 is moved will be described below.

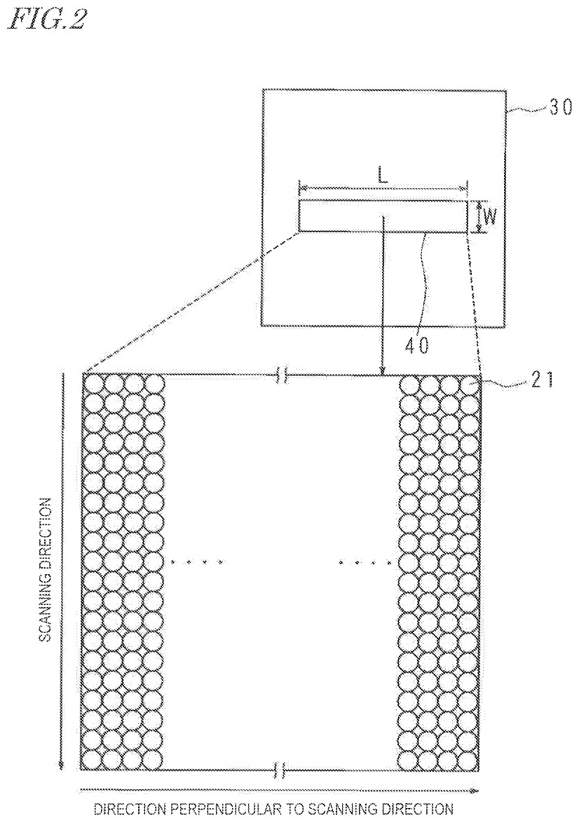

FIG. 2 is a schematic plan view showing an example configuration of the mask 30 of the present embodiment. The mask 30 includes the rectangular mask portion 40. The dimension of the mask portion 40 in the scanning direction (vertical direction) is denoted as W, and the dimension thereof in the direction (lateral direction) perpendicular to the scanning direction as L. The mask portion 40 includes an array of microlenses 21 arranged at regular intervals in the scanning direction and in the direction perpendicular to the scanning direction. Openings to be described below are formed at predetermined positions that are the positions of the centers of the microlenses 21 as seen from above.

The vertical dimension W of the mask portion 40 may be about 5 mm and the lateral dimension L may be about 50 mm, for example, but these dimensions are not limited thereto. Twenty microlenses 21 are arranged at regular intervals in the scanning direction vertical direction). Since each microlens 21 corresponds to one opening, the mask 30 includes 20 openings arranged at regular intervals n the scanning direction (vertical direction). In FIG. 2, each row of 20 openings provided along the scanning direction is referred to as an “opening row”. The mask 30 includes a plurality of opening rows arranged in the direction perpendicular to the scanning direction.

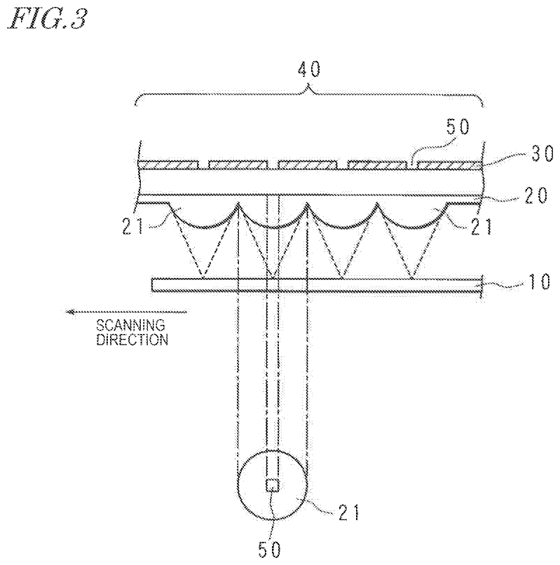

FIG. 3 is a schematic view showing the positional relationship between openings 50 and the microlenses 21 of the present embodiment. FIG. 3 shows the positional relationship between the openings 50 and the microlenses 21 as seen from above, and also shows the position of an opening 50 with respect to the position of the corresponding microlens 21 as seen from above. Note that the size of the opening 50 and the size of the irradiation pattern are drawn to be generally equal to each other in the present embodiment for the sake of illustration. In practice, however, laser light is converged through the microlens 21, and the size of the opening 50 is larger than the size of the irradiation pattern. As shown in FIG. 3, the mask portion 40 includes a plurality of openings 50 and a plurality of microlenses (lenses) 21. Note that the microlenses 21 are formed on a transparent substrate 20 corresponding to the openings 50, and the transparent substrate 20 and the mask 30 are integral with each other. The openings 50 are arranged so that the center of each microlens 21 having a circular shape as seen from above coincides with the center of the corresponding opening 50 having a rectangular shape as seen from above. The mask 30 and the light-receiving surface of the microlenses 21 are appropriately spaced apart from each other. The maximum size of the microlens 21 (the diameter of the circular shape as seen from above) may be set to about 150 μm to about 400 μm, for example, but is not limited thereto. A collection of microlenses 21 will be referred to also as a “microlens array”. Note that an opening 50 is herein also referred to simply as an “opening”, which includes one or more opening regions.

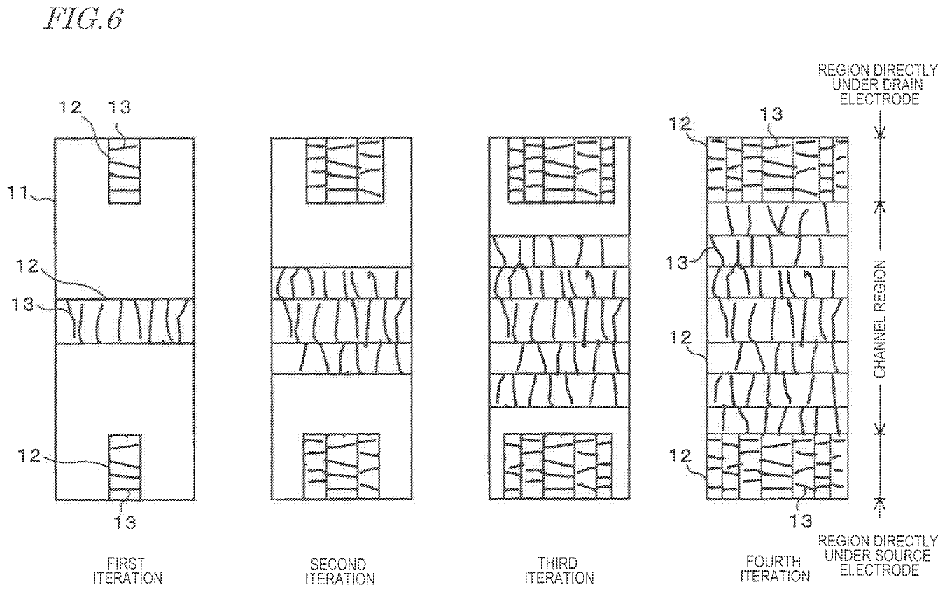

When the parallel beam shaped through the optical system 60 described above hits an opening 50 of the mask portion 40, the laser light having passed through the corresponding opening 50 is converged through the microlens 21, and the converged laser light selectively irradiates an intended location on the substrate 10 that corresponds to the opening 50 (i.e., the microlens 21). The intended location is typically a region to be a semiconductor layer (which may be referred to also as an “active layer”) of one TFT. As shown in FIG. 6, etc., a semiconductor layer (active layer) of one TFT includes a channel region, a source region and a drain region.

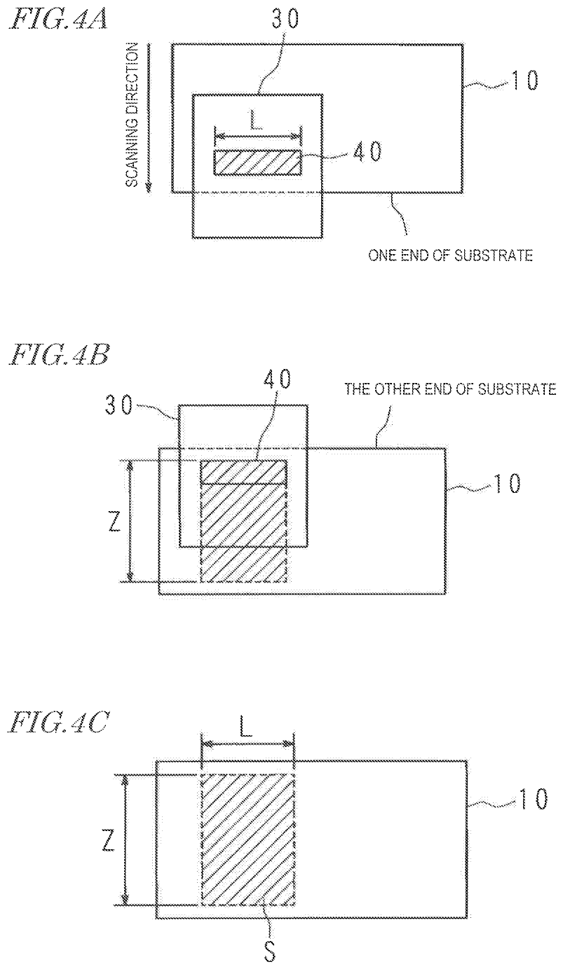

FIG. 4A, FIG. 4B and FIG. 4C are schematic views showing an example scan of the substrate 10 by the laser annealing apparatus 100 of the present embodiment. FIG. 4A shows a state where the mask 30 is set at a predetermined position, showing a state before the movement of the substrate 10 in the scanning direction is started. From the state shown in FIG. 4A, the substrate 10 is moved in the scanning direction at a constant speed. The laser light source 70 shoots laser light at time intervals such that laser light is shot each time an irradiation position of the substrate 10 arrives at a position corresponding to an opening 50. For example, with the openings 50 illustrated in FIG. 2, the same location of the substrate 10 is irradiated with laser light 20 times. FIG. 4B shows a state where the substrate 10 has been moved at a constant speed to the final position in the scanning direction (i.e., over the distance Z). By moving the substrate 10 to the state shown in FIG. 4B, the intended locations within an irradiation region S on the substrate 10 can be selectively irradiated with laser light as shown in FIG. 4C. In the state shown in FIG. 4C, by moving the mask 30 over the distance L in the direction perpendicular to the scanning direction, and moving the substrate 10 in the scanning direction as shown in FIG. 4A and FIG. 4b, it is possible to increase the irradiation region S. Note that while the size of the substrate 10 and the size of the mask 30 are shown to be similar to each other in FIG. 4, the size of the substrate 10 is in practice far larger than that shown in FIG. 4.

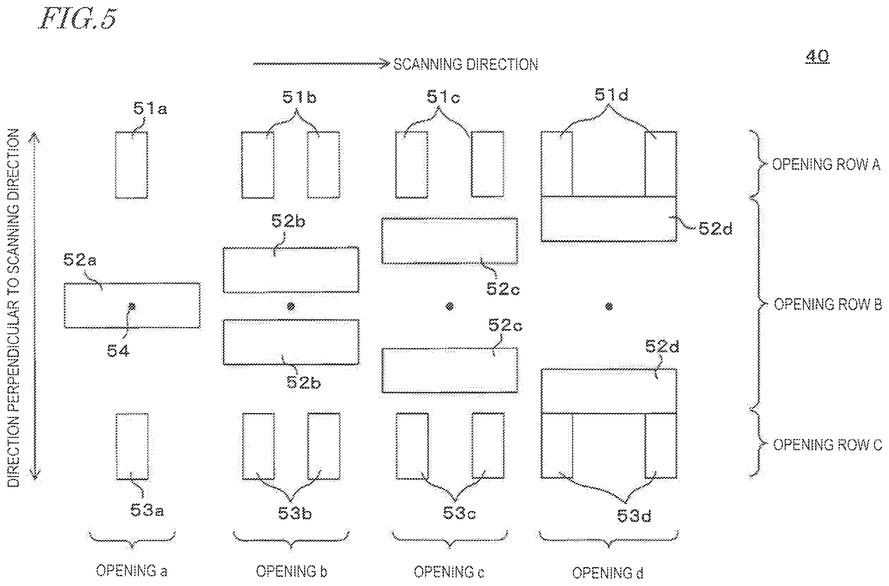

Next, the mask portion 40 of the mask 30 of the present embodiment will be described in detail. FIG. 5 is a schematic view showing a first example of openings of the mask portion 40 of the present embodiment. In the example below, for the sake of illustration, the mask portion 40 includes four different openings a, b, c and d provided along the direction parallel to the scanning direction. While four different openings a, b, c and d are shown to be adjacent to each other in the scanning direction in FIG. 5, this does not represent the positions of the openings in the scanning direction.

Each of the openings a, b, c and d is provided in the vicinity of a central position 54 of the corresponding one of the microlenses 21. Where the diameter of the microlens 21 is 250 μm, for example, each of the openings a, b, c and d is formed within a radius of 10 μm to 20 μm from the central position 54 of the corresponding microlens 21. The range over which the openings a, b, c and d are formed can be set appropriately so that the microlenses 21 can project, in reduced projection, with a sufficient precision the images of the openings a, b, c and d onto the surface of the semiconductor film. The number of times the semiconductor film is irradiated with laser light to melt the semiconductor film depends on the laser light irradiation energy density.

For example, the microlens array shown in FIG. 2 includes 20 (20 rows) of microlens 21 arranged in the scanning direction. The four different openings a, b, c and d are arranged corresponding to the 20 microlenses 21. For example, the opening a is arranged corresponding to microlenses 21 of the first row (the bottom row in FIG. 2) to the fifth row in the scanning direction, the opening b is arranged corresponding to microlenses 21 of the sixth row to the tenth row, the opening c is arranged corresponding to microlenses 21 of the eleventh row to the fifteenth row, and the opening d is arranged corresponding to microlenses 21 of the sixteenth row to the twentieth row.

Using the mask 30 including the four different openings a, b, c and d arranged as described above, regions of the semiconductor film to be the active layers of the TFTs are irradiated with laser light 20 times while moving the microlens array including 20 rows of microlenses 21 row by row relative to the substrate 10. Then, the region corresponding to the opening a is irradiated with laser light for the first to fifth shots, the region corresponding to the opening b is irradiated with laser light for the sixth to tenth shots, the region corresponding to the opening c is irradiated with laser light for the eleventh to fifteenth shots, and the region corresponding to the opening d is irradiated with laser light for the sixteenth to twelfth shots. That is, this example is a case where the amorphous semiconductor film is melted by being irradiated with laser light five times.

Needless to say, the arrangement of the four different openings a, b, c and d is not limited to that illustrated herein. For example, the order of the four different openings a, b, c and d may be changed (e.g., the opening b for the first to fifth rows, the opening a for the sixth to tenth rows, the opening d for the eleventh to fifteenth rows, and the opening c for the sixteenth to twenties rows). Note that the region that is crystallized by laser light irradiation (the polycrystalline region) is not melted unless it is heated to its melting point or higher. The temperature for melt-crystallizing the amorphous semiconductor film is lower than the melting point of the polycrystalline, and the laser light irradiation energy density, the irradiation time and the number of times of irradiation for melt-crystallizing an amorphous semiconductor film are set so that the semiconductor film is not heated to or above the melting point of the polycrystalline. Therefore, when the arrangement of the openings a, b, c and d is changed, the regions to be melt-crystallized will vary in accordance with the arrangement of the openings a, b, c and d.

The number of rows of the microlens array does not need to be 20 rows, but it may be four rows or more than 20 rows. It may be changed as necessary taking into consideration the laser light irradiation energy density, the oscillation time, the light-converging ability of microlenses and the reduction rate that is determined based on the distance between the microlenses and the semiconductor film, etc.

Each of the openings a, b, c and d includes a plurality of opening regions. Each of the openings a, b, c and d illustrated herein includes opening regions corresponding to the channel region (middle), the drain region (upper or lower) and the source region (lower or upper). Openings 52a, 52b, 52c and 52d for forming the channel region each have a rectangular shape that is elongated in the scanning direction (having a smaller width in the direction perpendicular to the scanning direction), whereas openings 51a, 51b, 51c and 51d for forming the drain region and openings 53a, 53b, 53c and 53d for forming the source region each have a rectangular shape that is elongated in the direction perpendicular to the scanning direction (having a smaller width in the scanning direction).

Thus, according to the embodiment of the present invention, the mask includes two or more opening regions that are elongated in two different directions, and regions of the semiconductor film corresponding to the opening regions are selectively irradiated with laser light and melted. That is, the regions of the semiconductor film corresponding to the opening regions (i.e., the regions onto which the opening regions are projected in reduced projection) are melted. The regions of the semiconductor film corresponding to the opening regions that are irradiated with laser light and melted may be referred to as the “melted regions”. The shape of a melted region is similar to the shape of the corresponding opening region. By the irradiation with laser light through two or more opening regions that are elongated in different directions, there are formed two or more elongate melted regions arranged in different directions, and it is therefore possible to form a semiconductor layer including a plurality of crystalline regions whose grain boundaries extend in different directions.

The plurality of opening regions of each of the openings a, b, c and d include opening regions corresponding to the channel region (middle), the drain region (upper or lower) and the source region (lower or upper). That is, a plurality opening regions of each of the openings a, b, c and d can be expressed as three opening rows A, B and C as shown in FIG. 5. Needless to say, the number of opening rows of the mask according to the embodiment of the present invention and the number of openings in each opening row are not limited to those of the example of FIG. 5.

As shown in FIG. 5, each of the opening rows A, B and C includes the openings a, b, c and d arranged in the scanning direction. The opening row B can be referred to as the first opening row, and the opening row A and the opening row C can be referred to as the second opening row. Where the opening a is regarded as the first opening, the opening b can be regarded as the second opening. The relationship between the opening b and the opening c and the relationship between the opening c and the opening d are also similar to the relationship between the opening a and the opening b.

As shown in FIG. 5, in the opening row A (referred to also as the “second opening row”), the opening a includes the opening region 51a, the opening b includes the opening region 51b, the opening c includes the opening region 51c, and the opening d includes the opening region 51d. In the opening row B, the opening a includes the opening region 52a, the opening b includes the opening region 52b, the opening c includes the opening region 52c, and the opening d includes the opening region 52d. Similarly, in the opening row C, the opening a includes the opening region 53a, the opening b includes the opening region 53b, the opening c includes the opening region 53c, and the opening d includes the opening region 53d. In each row, the opening a includes only one opening region, and the openings b to d each include only two opening regions.

Each of the opening regions of the opening row A and the opening row C has a rectangular shape. More specifically, the opening regions 51a to 51d and 53a to 53d each have a shape elongated in the direction perpendicular to the scanning direction. Each of the opening regions of the opening row B also has a rectangular shape. More specifically, the opening regions 52a to 52d each have a shape elongated in the scanning direction. Note that the shapes of the opening regions of FIG. 5 are shown for the sake of illustration, and the actual opening regions may have shapes different from those shown in FIG. 5. The width (the dimension in the scanning direction) of the opening regions 51a to 51d and 53a to 53d may be some μm, for example. The width (the dimension in the direction perpendicular to the scanning direction) of the opening regions 52a to 52d may be some μn, for example.

An elongated rectangular shape as used herein refers to a shape whose aspect ratio (long side/short side) is three or more, and the length of the short side is 4 μm or less, for example. If the length of the short side exceeds 4 μm, the lateral growth may not reach the center of the melted region during crystallization, resulting in microcrystals occurring in the middle of the melted region. Note that the shape of each opening region is not limited to a rectangular shape, but may be an elliptical shape, for example, in which case the aspect ratio can be defined as major axis/minor axis. An opening region may have a shape other than a rectangular shape or an elliptical shape, in which case the shape is preferably line-symmetrical with respect to the major axis and the minor axis.

In the opening row B, where the opening a is regarded as the first opening and the opening b as the second opening, the opening region 52a (the first opening region) and the opening region 52b (the second opening region) are arranged next to each other in the direction parallel to the scanning direction. When opening regions are shifted so that the central position 54 of the opening a coincides with the central position 54 of the opening b, the opening region 52b includes an opening region that is obtained by displacing a region corresponding to the opening region 52a at the opening b (the second opening) in the direction perpendicular to the scanning direction.

Similarly, in the opening row B, where the opening b is regarded as the first opening and the opening c as the second opening, the opening region 52b (the first opening region) and the opening region 52c (the second opening region) are arranged next to each other in the direction parallel to the scanning direction. When opening regions are shifted so that the central position 54 of the opening b coincides with the central position 54 of the opening c, the opening region 52c includes an opening region that is obtained by displacing a region corresponding to the opening region 52b at the opening c (the second opening) in the direction perpendicular to the scanning direction. The relationship between the opening c and the opening d is similar to this.

In the opening row A, when the opening a is regarded as the first opening and the opening b as the second opening, the opening region 51a (the first opening region) and the opening region 51b (the second opening region) are arranged next to each other in the direction parallel to the scanning direction. When opening regions are shifted so that the central position 54 of the opening a coincides with the central position 54 of the opening b, the opening region 51b includes an opening region that is obtained by displacing a region corresponding to the opening region 51a at the opening b (the second opening) in the direction parallel to the scanning direction.

Similarly, in the opening row A, where the opening b is regarded as the first opening and the opening c as the second opening, the opening region 51b (the first opening region) and the opening region 51c (the second opening region) are arranged next to each other in the direction parallel to the scanning direction. When opening regions are shifted so that the central position 54 of the opening b coincides with the central position 54 of the opening c, the opening region 51c includes an opening region that is obtained by displacing a region corresponding to the opening region 51b at the opening c (the second opening) in the direction parallel to the scanning direction. The relationship between the opening c and the opening d is similar to this. The opening row C is similar to the opening row A.

Although four openings a, b, c and d are arranged adjacent to each other in the scanning direction in the description above, five of each of the openings a, b, c and d may be arranged in the scanning direction as described above with reference to FIG. 2. Even in such a case, there are a location where the opening a and the opening b are adjacent to each other, a location where the opening b and the opening c are adjacent to each other, and a location where the opening c and the opening d are adjacent to each other, as described above.

Next, grain boundaries will be described. When an amorphous silicon (non-crystalline, a-Si) film is irradiated with laser light, the amorphous silicon film is hot-melted. The crystal growth advances with the hot-melted amorphous silicon solidifying inwardly from the laser light irradiation region boundary. The crystallized region of the semiconductor film has a structure (polycrystal line structure) that is a collection of many regions (referred to also as the “crystal grains”) where atoms are arranged in different directions, and boundaries between crystal grains are referred to as grain boundaries. Where the laser light irradiation region is an elongate rectangular shape, crystals that grow from the opposing boundaries along the width direction inwardly come close to each other, resulting in the direction of grain boundaries being generally the width direction. Note that since the directions of individual grain boundaries vary, the direction of a grain boundary as used herein means the average direction among the grain boundaries included in the crystallized region, referring to the general direction of the crystal grains as a whole.

FIG. 6 is a schematic view showing an example of how an amorphous silicon film grows using the laser annealing apparatus 100 of the present embodiment. The crystal growth shown in FIG. 6 is an example where the openings shown in FIG. 5 are used.

FIG. 6 shows the channel region, the region (the source region) directly under the source electrode and the region (the drain region) directly under the drain electrode, which are on the opposite sides of the channel region. The reference sign 11 denotes an amorphous silicon film, and the reference sign 12 denotes a polysilicon film. The reference sign 13 denotes grain boundaries. FIG. 6 schematically shows how crystals grow in the amorphous silicon film, which is the laser light irradiation region, showing, left to right, how crystals grow over the number of iterations of laser light irradiation (from the first iteration to the fourth iteration). Note that the first iteration is when laser light is shot through the opening a, the second iteration is when laser light is shot through the opening b, the third iteration is when laser light is shot through the opening c, and the fourth iteration is when laser light is shot through the opening d. Where laser light is shot five times, for example, through each of the openings a, b, c and d, the figure schematically shows grain boundaries after the fifth not.

The first iteration in FIG. 6 shows the crystal growth in the irradiation region when laser light is shot through the opening a shown in FIG. 5. The opening region 52a has a rectangular shape elongated in the direction parallel to the scanning direction (referred to also as the “lateral direction”), and the width dimension thereof along the direction perpendicular to the scanning direction (which is referred to also as the vertical direction) is small. Therefore, the hot-melted amorphous silicon film 11 solidifies inwardly from the opposing boundaries in the lateral direction of the irradiation region corresponding to the opening region 52a, forming the polysilicon film 12. In this case, the direction of grain boundaries 13 is the vertical direction.

The opening region 51a has a rectangular shape elongated in the vertical direction and the width dimension thereof along the lateral direction is small. Therefore, the hot-melted amorphous silicon film 11 solidifies inwardly from the opposing boundaries in the vertical direction of the irradiation region corresponding to the opening region 51a, forming the polysilicon film 12. In this case, the direction of grain boundaries 13 is the lateral direction. With the opening region 53a, similar to the opening region 51a, the film solidifies inwardly from the opposing boundaries in the vertical direction of the irradiation region corresponding to the opening region 53a, forming the polysilicon film 12. In this case, the direction of grain boundaries 13 is the lateral direction.

The second iteration shows the crystal growth in the irradiation region when laser light is shot through the opening b shown in FIG. 5. The opening region 52b includes two opening regions spaced apart from each other in the vertical direction with a region corresponding to the opening region 52a interposed therebetween, and the opening region 52b forms a rectangular shape elongated in the lateral direction and the width dimension thereof along the vertical direction is small. Therefore, the hot-melted amorphous silicon film 11 solidifies inwardly from the opposing boundaries in the lateral direction of the irradiation region corresponding to the opening region 52b, forming the polysilicon film 12. In this case, the direction of grain boundaries 13 is the vertical direction.

The opening region 51b includes two opening regions spaced apart from each other in the lateral direction with a region corresponding to the opening region 51a interposed therebetween, and the opening region 51b forms a rectangular shape elongated in the vertical direction and the width dimension thereof along the lateral direction is small. Therefore, the hot-melted amorphous silicon film 11 solidifies inwardly from the opposing boundaries in the vertical direction of the irradiation region corresponding to the opening region 51b, forming the polysilicon film 12. In this case, the direction of grain boundaries 13 is the lateral direction. With the opening region 53b, similar to the opening region 51b, the film solidifies inwardly from the opposing boundaries in the vertical direction of the irradiation region corresponding to the opening region 53b, forming the polysilicon film 12. In this case, the direction of grain boundaries 13 is the lateral direction.

As the laser light irradiation is repeated for the third iteration and the fourth iteration as shown in FIG. 6, the direction of grain boundaries in the channel region is parallel to the longitudinal direction of the channel region (i.e., the direction perpendicular to the scanning direction), and the direction of grain boundaries in the region directly under the drain electrode and the region directly under the source electrode is the direction perpendicular to the longitudinal direction of the channel region (i.e., the scanning direction), as shown in “Fourth iteration” in FIG. 6.

In grain boundaries, electrons tend to be scattered, resulting in a low electron mobility. In the channel region, since the direction of grain boundaries is the longitudinal direction of the channel region, the degree by which electrons are scattered by grain boundaries is small, and it is possible to realize a large ON current of the thin film transistor. In regions directly under the source electrode and the drain electrode, the direction of grain boundaries is the direction perpendicular to the longitudinal direction of the channel region, for example, and it is therefore possible to increase the frequency with which electrons pass through grain boundaries and reduce the OFF current of the thin film transistor.

As described above, in the opening row B (the first opening row), the irradiation region of the semiconductor film is irradiated with laser light through the opening region 52a, and grain boundaries in the region irradiated with laser light grow in a predetermined direction (e.g., the direction perpendicular to the scanning direction). At the point in time for the next laser light irradiation, the irradiation region is irradiated with laser light through the opening region 52b. In this case, since the opening region 52b includes an opening region that is obtained by displacing the region corresponding to the opening region 52a in a predetermined direction different from the scanning direction, grain boundaries further grow in the predetermined direction. This similarly applies to the opening regions 52c and 52d. Thus, grain boundaries can be made to grow in intended directions (e.g., the direction perpendicular to the scanning direction), without being limited to the substrate scanning direction.

As described above, in the opening row A (the second opening row), the irradiation region of the semiconductor film is irradiated with laser light through the opening region 51a, and grain boundaries in the region irradiated with laser light grow in the direction parallel to the scanning direction. At the point in time for the next laser light irradiation, the irradiation region is irradiated with laser light through the opening region 51b. In this case, since the opening region 51b includes an opening region that is obtained by displacing the region corresponding to the opening region 51a in the direction parallel to the scanning direction, grain boundaries further grow in the direction parallel to the scanning direction. This similarly applies to the opening regions 51c and 51d. The opening row C (the second opening row) is similar to the opening row A. Thus, it is possible to produce a structure having different grain boundaries on the same substrate. For example, grain boundaries can be made to grow in different directions (in the scanning direction and in the direction perpendicular to the scanning direction in the example of FIG. 5 and FIG. 6).

In the example described above, in the opening row B, the opening region 52b does not include a portion of the region corresponding to the opening region 52a at the opening b. That is, the opening region 52b is divided into two opening regions with a portion of the region corresponding to the opening region 52a interposed therebetween. Thus, when laser light is shot through the opening region 52b of the opening b, a part or whole of the crystalline semiconductor film corresponding to the region between the two opening regions 52b (the polycrystalline semiconductor region) may be blocked from laser light irradiation. This similarly applies to the opening regions 52c and 52d. This similarly applies to the opening row A and the opening row C. By performing the next laser light irradiation so as to partially overlap with the region crystallized by the previous laser light irradiation, crystals that have been produced through the previous laser light irradiation can grow continuously. Note that the region crystallized through the previous laser light irradiation (the polycrystalline semiconductor region) may be irradiated with laser light under conditions (the laser light irradiation energy density, the irradiation time and the number of times of irradiation) such that polycrystalline does not melt even when irradiated again with laser light. This is because grain boundaries can similarly be formed continuously.

The predetermined direction may be the direction perpendicular to the scanning direction. Then, it is possible to form, on the substrate surface, grain boundaries extending in the vertical direction and grain boundaries extending in the lateral direction.

As shown in FIG. 5, each opening region forms a rectangular shape. In the opening row B, the opening regions 52a to 52d may be shaped to be elongated in the direction parallel to the scanning direction, whereas in the opening row A and the opening row C, the opening regions 51a to 51d and 53a to 53d may be shaped to be elongated in a predetermined direction different from the scanning direction (the direction perpendicular to the scanning direction). Thus, the direction of grain boundaries can be an intended direction.

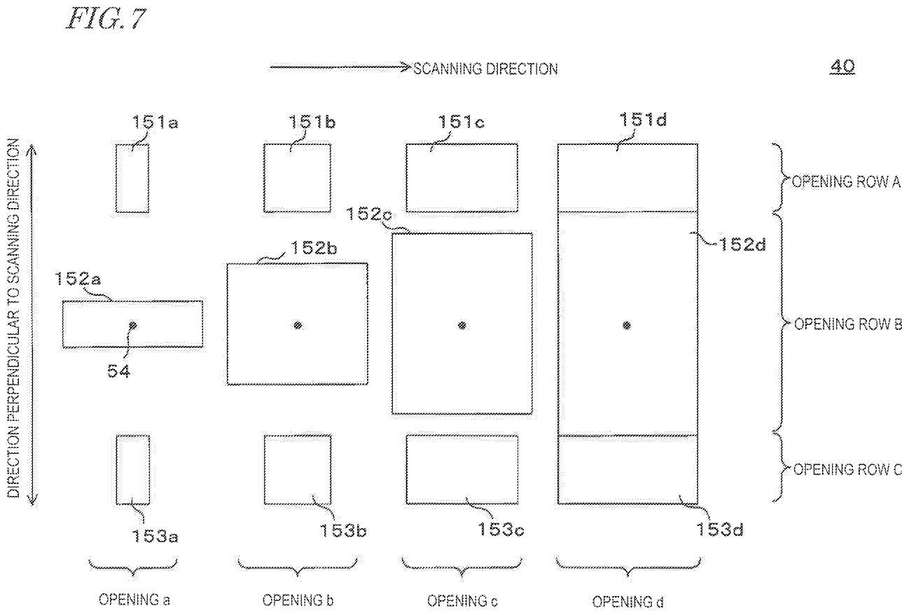

FIG. 7 is a schematic view showing a second example of the openings 50 of the mask portion 40 of the present embodiment. In the first example shown in FIG. 5, in the opening row B, the opening region 52b does not include a portion of the region corresponding to the opening region 52a at the opening b as shown in FIG. 5, for example. That is, the opening region 52b is divided into two opening regions with a portion of the region corresponding to the opening region 52a interposed therebetween.

On the other hand, in the second example, in the opening row B, an opening region 152b includes a region corresponding to an opening region 152a at the opening b as shown in FIG. 7. That is, the opening region 152b is a single opening region that includes a region corresponding to the opening region 152a. Thus, when laser light is shot through the opening region 152b of the opening b, the region irradiated with laser light through the opening region 152a of the opening a is irradiated again with laser light. In this process, if the region crystallized through the previous laser light irradiation (the polycrystalline semiconductor region) is irradiated with laser light under conditions (the laser light irradiation energy density, the irradiation time and the number of times of irradiation) such that polycrystalline does not melt even when irradiated again with laser light, it is possible to substantially form the polycrystalline semiconductor region shown in FIG. 6. Typical laser light irradiation conditions for crystallizing amorphous silicon satisfy those conditions described above. This similarly applies to opening regions 152c and 152d. This similarly applies to the opening row A and the opening row C.

Thus, even if the region to be irradiated with laser light in the second or subsequent iteration includes a region that has been previously irradiated with laser light and crystallized, the previously crystallized region is not melted. Therefore, if an amorphous region, of the region to be irradiated with laser light in the second or subsequent iteration, has an elongate shape, it is possible to form a polycrystalline semiconductor region having grain boundaries extending in a predetermined direction. Therefore, although the opening regions 152b, 152c and 152d of FIG. 7 do not have a shape elongated in the lateral direction as does the opening region 152a, it is possible to melt-crystallize the same regions as with the pairs of opening regions 52b, 52c and 52d shown in FIG. 5. Similarly, although opening regions 151b, 151c and 151d of FIG. 7 do not have a shape elongated in the vertical direction as does an opening region 151a, it is possible to melt-crystallize the same regions as with the pairs of opening regions 51b, 51c and 51d shown in FIG. 5. Although opening regions 153b, 153c and 153d of FIG. 7 do not have a shape elongated in the vertical direction as does an opening region 153a, it is possible to melt-crystallize the same regions as with the pairs of opening regions 53b, 53c and 53d shown in FIG. 5.

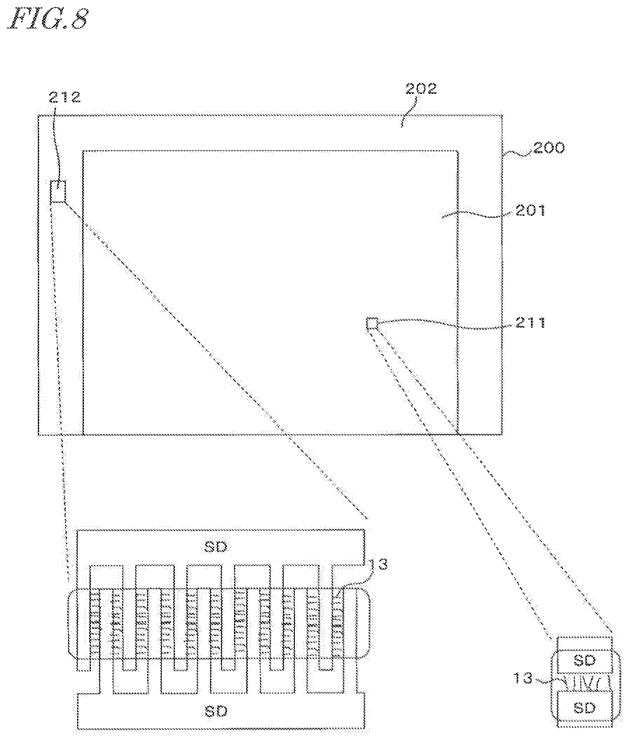

FIG. 8 is a schematic view showing an example of a display panel 200 including thin film transistors having active layers annealed by the laser annealing apparatus 100 of the present embodiment. The crystallization through laser light irradiation described above is referred to as an annealing process.

The display panel 200 includes a rectangular pixel region 201, and a peripheral circuit section 202 provided around the pixel region 201, etc. One of the two designations “SD” refers to the source electrode (&) and the other refers to the drain electrode (D). In a GOA (Gate Driver On Array) circuit section 212 in the peripheral circuit section 202, the direction of grain boundaries in the channel region between the source electrode and the drain electrode may be the lateral direction, and in a pixel portion 211 of the pixel region 201, the direction of grain boundaries in the channel region between the source electrode and the drain electrode may be the vertical direction. Thus, the direction of grain boundaries can be varied between the pixel portion and the peripheral circuit. That is, two different thin film transistors, of which the longitudinal directions of the channel regions are perpendicular to each other, can be formed on the same substrate. Therefore, the positions of the drain electrode and the source electrode with respect to the channel region can be changed freely in the vertical direction and in the lateral direction, and it is possible to increase the degree of freedom in designing circuits on the substrate. It is possible to realize a display panel having thin film transistors, wherein grain boundaries are made to grow in intended directions, without being limited to the substrate scanning direction.

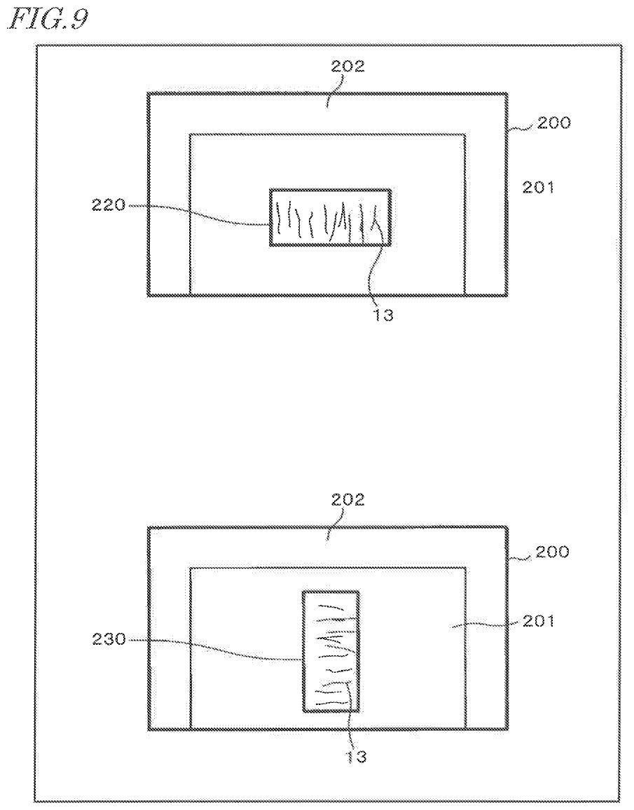

FIG. 9 is a schematic view showing another example of display panels 200 including thin film transistors having active layers annealed by the laser annealing apparatus 100 of the present embodiment. The example of FIG. 9 shows how two display panels 200 are produced from a single glass substrate. Each display panel 200 includes the rectangular pixel region 201, and the peripheral circuit section 202 provided around the pixel region 201, etc. The pixel region 201 of the upper display panel 200 includes a group of thin film transistors 220, wherein the direction of grain boundaries 13 in the channel region is the vertical direction. The pixel region 201 of the lower display panel 200 includes a group of thin film transistors 230, wherein the direction of grain boundaries 13 in the channel region is the lateral direction. Thus, the direction of grain boundaries can be varied within a substrate. Since the direction of grain boundaries can be set to any direction, an experiment on the direction of grain boundaries can be performed at once within a substrate.

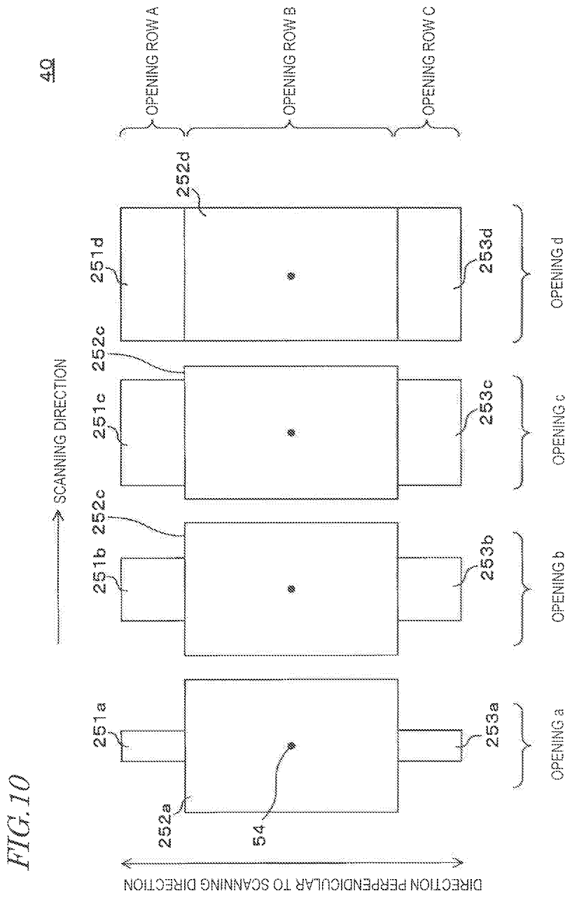

FIG. 10 is a schematic view showing a third example of the openings 50 of the mask portion 40 of the present embodiment. Opening regions 251a to 251d of the opening row A are similar to the opening regions 151a to 151d of the second example shown in FIG. 7. Opening regions 253a to 253d of the opening row C are similar to the opening regions 153a to 153d of the second example shown in FIG. 7. A difference from the second example is that opening regions 252a to 252d of the opening row B have a rectangular shape of the same size, and have generally the same vertical and lateral dimensions as those of the channel region.

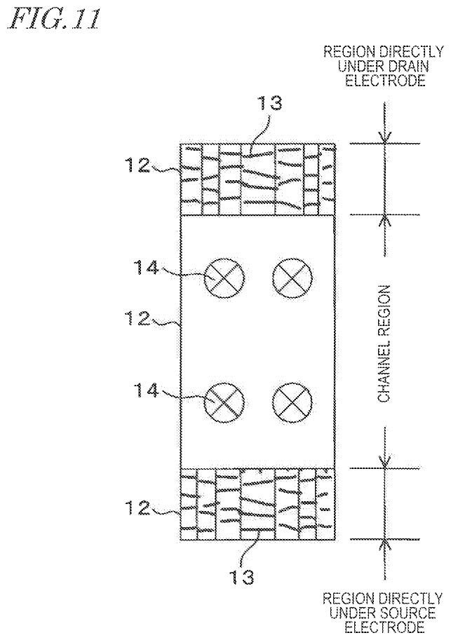

FIG. 11 is a schematic view showing an example of how grain boundaries grow in regions that are crystallized using the mask portion 40 shown in FIG. 10. When repeatedly irradiated with laser light through the opening regions 252a to 252d of the opening row B, there are formed polycrystalline regions in the channel region where grain boundaries 14 extend in the thickness direction (the direction from the near side toward the far side on the drawing sheet, i.e., the direction toward the gate electrode), as shown in FIG. 11. Since the size of the opening regions 252a to 252d is large, the lateral growth does not reach the central ort ion of the melted region during crystallization, resulting in microcrystals formed in much of the melted region. As the direction of grain boundaries in the channel region is set to the thickness direction of the channel region, it is possible to increase the frequency with which electrons pass through grain boundaries and reduce the OFF current of the thin film transistor. This can be realized by appropriately setting the laser light irradiation conditions (the laser light irradiation energy density, the irradiation time and the number of times of irradiation) for each of the openings a to d. That is, the laser light irradiations conditions may vary between the openings a to d.

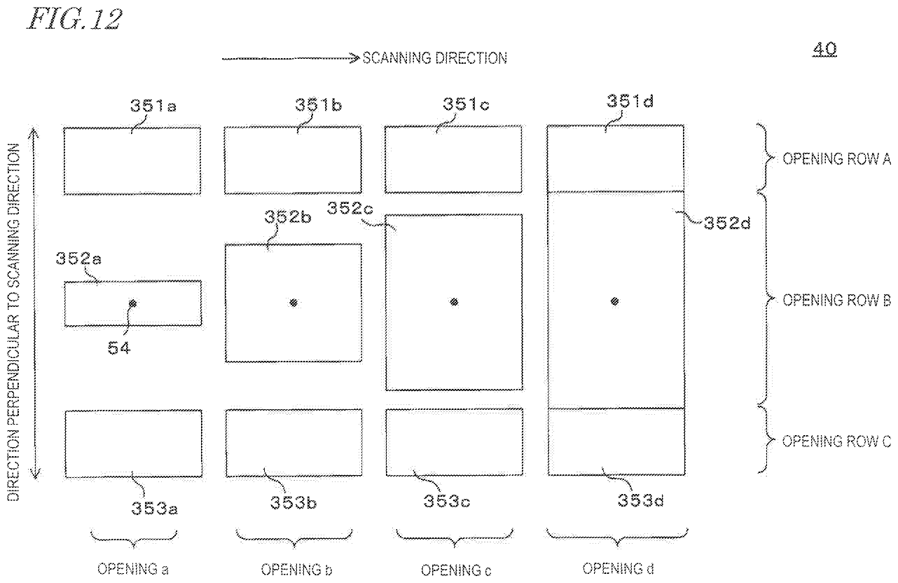

FIG. 12 is a schematic view snowing a fourth example of the openings 50 of the mask portion 40 of the present embodiment. Opening regions 352a to 352d of the opening row B are similar to the opening regions 152a to 152d of the second example shown in FIG. 7. A difference from the second example is that opening regions 351a to 351d of the opening row A have a rectangular shape of the same size, and have generally the same vertical and lateral dimensions as those of the region directly under the drain electrode. Opening regions 353a to 353d of the opening row C have an elongate shape of the same size, and have generally the same vertical and lateral dimensions as those of the region directly under the source electrode.

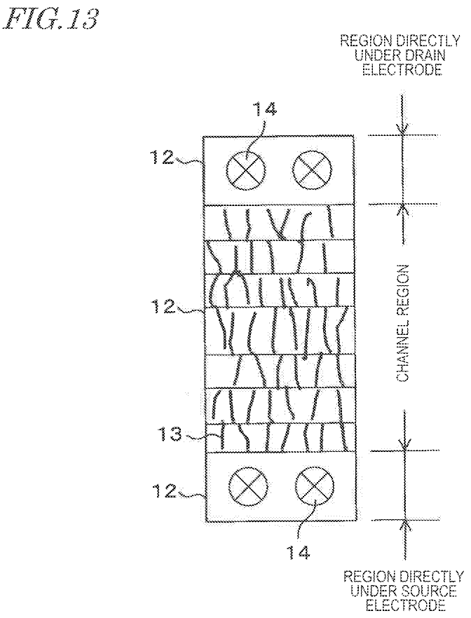

FIG. 13 is a schematic view showing an example of how grain boundaries grow in regions that are annealed by the mask portion 40 shown in FIG. 12. As shown in FIG. 13, since the region directly under the drain electrode and the region directly under the source electrode are irradiated with laser light repeatedly (four times in the example of FIG. 12 for the sake of illustration), the direction of grain boundaries 14 is the thickness direction (the direction from the near side toward the far side on the drawing sheet, i.e., the direction toward the gate electrode). In the region directly under the drain electrode and the region directly under the source electrode, the direction of grain boundaries is the direction vertical to the drain electrode and the source electrode. Therefore, the degree by which electrons are scattered by grain boundaries is small, and it is possible to increase the ON current of the thin film transistor.

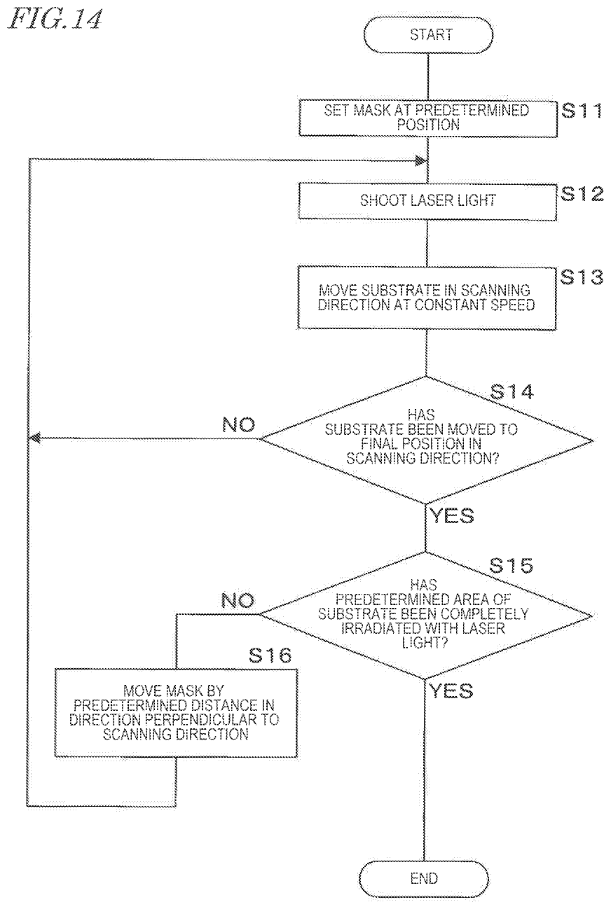

Next, a laser annealing method using the laser annealing apparatus 100 of the present embodiment will be described. FIG. 14 is a flow chart showing an example of a laser annealing method using the laser annealing apparatus 100 of the present embodiment. Hereinafter, the laser annealing apparatus 100 will be referred to as the apparatus 100 for the sake of illustration. The apparatus 100 sets the mask 30 at a predetermined position (S11), and shoots laser light (S12). The apparatus 100 moves the substrate 10 in the scanning direction at a constant speed (S13). The laser light source 70 shoots laser light at time intervals such that laser light is shot each time an irradiation position of the substrate 10 arrives at a position corresponding to an opening 50 of the mask 30.

The apparatus 100 determines whether or not the substrate 10 has been moved to the final position in the scanning direction (S14), and repeats the process of step 312 and subsequent steps if the substrate 10 has not been moved to the final position (NO in S14). If the substrate 10 has been moved to the final position in the scanning direction (YES in S14), the apparatus 100 determines whether or not a predetermined area of the substrate 10 has been completely irradiated with laser light (3.1.5).

If a predetermined area of the substrate 10 has not been completely irradiated with laser light (No in S15), the apparatus 100 moves the mask 30 by a predetermined distance (the dimension L of the mask 30 in the lateral direction) in the direction perpendicular to the scanning direction (516), and repeats the process of step S12 and subsequent steps. If a predetermined area of the substrate 10 has been completely irradiated with laser light (YES in S15), the apparatus 100 ends the process. Note that the substrate 10 is moved (transferred) in the scanning direction in the example of FIG. 14, but the present invention is not limited thereto. The substrate 10 may be fixed, and the mask 30 (optionally including the optical system 60) may be moved in the scanning direction.

Particularly, by performing partial laser annealing using the mask 30 of the present embodiment, the crystal grain growth direction (the direction of grain boundaries) by an SLS method can be a plurality of directions on the substrate surface. Microscopically, in the thin film transistor, the direction of grain boundaries in the channel region may be varied from the direction of grain boundaries in the regions directly under the source electrode and the drain electrode. Thus, thin film transistors for pixels and thin film transistors for driver circuit area outside the display area, etc., can be freely arranged without being restricted by the direction of grain boundaries, thus increasing the degree of freedom in circuit design.

While the openings a, b, c and d are arranged in this order in the scanning direction in the embodiment described above, the present invention is not limited thereto, and the openings a, b, c and d may be arranged in this order in the direction opposite to the scanning direction.

While the shape of each of the opening regions of the openings 50 is a rectangular shape in the embodiment described above, the shape of an opening region is not limited to a rectangular shape but may be an elliptical shape, for example. The four corners of a rectangular opening region may be cut off in a circular or rectangular shape. Then, it is possible to slightly increase the amount of laser light irradiation in the vicinity of the four corners of the opening region, and the region to be irradiated with laser light can be shaped in a rectangular shape.

The present embodiment can be applied not only to TFTs using a silicon semiconductor but also to TFTs using an oxide semiconductor, and it is possible to perform an annealing process wherein the electron mobility is partially varied within one cycle of scan.

A laser annealing apparatus according to the present embodiment is a laser annealing apparatus including a mask having an opening row, wherein the opening row includes openings each including an opening region and arranged in a scanning direction, for irradiating a substrate with laser light through the openings, wherein a first opening including a first opening region and a second opening including a second opening region are arranged next to each other in a direction parallel to the scanning direction, and the mask has a first opening row in which the second opening region includes an opening region that is obtained by displacing a region corresponding to the first opening region at the second opening in a predetermined direction different from the scanning direction.

A laser annealing method according to the present embodiment includes: step A of providing a substrate having an amorphous semiconductor film formed on a surface thereof; and step B of selectively irradiating a portion of the amorphous semiconductor film with laser light, wherein step B includes a step of simultaneously forming, in said portion, a first melted region that is elongated in a first direction and a second melted region that is elongated in a second direction different from the first direction.

A mask according to the present embodiment is a mask having an opening row, wherein the opening row includes openings each including an opening region and arranged in a scanning direction, wherein a first opening including a first opening region and a second opening including a second opening region are arranged next to each other in a direction parallel to the scanning direction, and the mask has an opening row in which the second opening region includes an opening region that is obtained by displacing a region corresponding to the first opening region at the second opening in a predetermined direction different from the scanning direction.

An opening includes one or more opening regions. An opening row includes a plurality of openings arranged in a scanning direction. Where N openings are arranged along one opening row, for example, by shifting a substrate including a semiconductor film formed thereon in the scanning direction, an intended region of the semiconductor film is repeatedly irradiated with laser light N times. The mask may include a plurality of opening rows.

A first opening including a first opening region and a second opening including a second opening region are arranged next to each other in a direction parallel to the scanning direction.

That is, the first opening region a of the first opening and the second opening region b of the second opening are arranged next to each other in the direction parallel to the scanning direction. Where the region corresponding to the first opening region a at the second opening is denoted as the region a′, the second opening region b in the first opening row includes, at the second opening, an opening region that is obtained by displacing the region a′ in a predetermined direction different from the scanning direction.

Assume that a semiconductor film is irradiated with laser light through the first opening region a, and grain boundaries grow in a predetermined direction in the region irradiated with laser light. At the point in time for the next laser light irradiation, laser light is shot through the second opening region b. In this case, since the second opening region b includes an opening region that is displaced from the region a′ in a predetermined direction different from the scanning direction, grain boundaries further grow in the predetermined direction. Thus, grain boundaries can be made to grow in intended directions, without being limited to the substrate scanning direction.

In a laser annealing apparatus according to the present embodiment, the mask has a second opening row in which the second opening region includes an opening region that is obtained by displacing a region corresponding to the first opening region at the second opening in a direction parallel to the scanning direction.

The opening region a of the first opening and the second opening region b of the second opening are arranged next to each other in a direction parallel to the scanning direction. Where the region corresponding to the first opening region a at the second opening is denoted as the region a′, the second opening region b in the second opening row includes, at the second opening, an opening region that is obtained by displacing the region a′ in a direction parallel to the scanning direction.

Assume that a semiconductor film is irradiated with laser light through the first opening region a, and grain boundaries grow in the scanning direction in the region irradiated with laser light. At the point in time for the next laser light irradiation, laser light is shot through the second opening region b. In this case, since the second opening region b includes an opening region that is displaced from the region a′ in a direction parallel to the scanning direction, grain boundaries further grow in the scanning direction. Thus, it is possible to produce a structure having different grain boundaries on the same substrate. For example, grain boundaries can be made to grow in different directions.

In a laser annealing apparatus according to the present embodiment, the second opening region does not include a portion of the region corresponding to the first opening region at the second opening.

The second opening region b does not include a portion of the region a′ corresponding to the first opening region a at the second opening. Thus, where laser light is snot through the second opening, a crystalline semiconductor film corresponding to the region a′ can be prevented from being irradiated with laser light, and it is possible to easily realize intended characteristics of the crystalline semiconductor film.

In a laser annealing apparatus according to the present embodiment, the second opening region includes a region corresponding to the first opening region at the second opening.

The second opening region b includes the region a′ corresponding to the first opening region a at the second opening. Thus, where laser light is shot through the second opening, a crystalline semiconductor film corresponding to the region a′ can also be irradiated with laser light, and it is possible to easily realize intended characteristics of the crystalline semiconductor film.

In a laser annealing apparatus according to the present embodiment, the predetermined direction is a direction perpendicular to the scanning direction.

The predetermined direction is a direction perpendicular to the scanning direction. Then, it is possible to form, on the substrate surface, grain boundaries extending in the vertical direction and grain boundaries extending in the lateral direction.

In a laser annealing apparatus according to the present embodiment, the first opening region and the second opening region each form a rectangular shape.

The first opening region a and the second opening region b each form a rectangular shape. For example, in the first opening row, the first opening region a and the second opening region b can have a shape elongated in the scanning direction, and in the second opening row, the first opening region a and the second opening region b can have a shape elongated in a predetermined direction different from the scanning direction. Thus, the direction of grain boundaries can be an intended direction.

A display panel according to the present embodiment includes a thin film transistor annealed by a laser annealing apparatus according to the present embodiment.

It is possible to realize a display panel having thin film transistors, wherein grain boundaries are made to grow in intended directions, without being limited to the substrate scanning direction.

In a display panel according to the present embodiment, the thin film transistor includes: a gate electrode formed on a surface of a substrate; a crystalline semiconductor film formed on an upper side of the gate electrode; a source electrode formed on the crystalline semiconductor film; and a drain electrode formed on the crystalline semiconductor film, wherein a direction of grain boundaries in the crystalline semiconductor film, which forms a channel region between the source electrode and the drain electrode, is parallel to a longitudinal direction of the channel region, and a direction of grain boundaries in the crystalline semiconductor film directly under the source electrode and the drain electrode is different from the longitudinal direction.

The direction of grain boundaries of the crystalline semiconductor film, which forms the channel region between the source electrode and the drain electrode, may be parallel to the longitudinal direction of the channel region, and the direction of grain boundaries of the crystalline semiconductor film directly under the source electrode and the drain electrode may be a direction different from the longitudinal direction of the channel region (e.g., the direction perpendicular to the longitudinal direction).

In grain boundaries, electrons tend to be scattered, resulting in a low electron mobility. In the channel region, since the direction of grain boundaries is the longitudinal direction of the channel region, the degree by which electrons are scattered by grain boundaries is small, and it is possible to realize a large ON current of the thin film transistor. The direction of grain boundaries in the region directly under the source electrode and the region directly under the drain electrode may be the direction perpendicular to the longitudinal direction of the channel region, for example, and it is then possible to increase the frequency with which electrons pass through grain boundaries and reduce the OFF current of the thin film transistor.

A display panel according to the present embodiment includes: a first thin film transistor in which a direction of grain boundaries in a crystalline semiconductor film, which forms a channel region, is a predetermined direction; and a second thin film transistor in which a direction of grain boundaries in the crystalline semiconductor film, which forms the channel region, is a direction different from the predetermined direction.

The display panel includes a first thin film transistor in which the direction of grain boundaries in the crystalline semiconductor film, which forms the channel region, is a predetermined direction, and a second thin film transistor in which the direction of grain boundaries in the crystalline semiconductor film, which forms the channel region, is a direction different from the predetermined direction (e.g., the direction perpendicular to the predetermined direction). Then, thin film transistors of which the longitudinal directions of the channel regions are perpendicular to each other, for example, can be formed on the same substrate. Therefore, the positions of the drain electrode and the source electrode with respect to the channel region can be changed freely in the vertical direction and in the lateral direction, and it is possible to increase the degree of freedom in designing circuits on the substrate.

The elements described in the examples above can be combined with each other, and any such combination may bring forth a new technical, feature.

The present application claims priority of Japanese Patent Application No. 2018-143165, filed on Jul. 31, 2018, the entire contents of which are hereby incorporated by reference.

1-4. (canceled)

5. A laser annealing method comprising:
step A of preparing a substrate having an amorphous semiconductor film formed on a surface thereof; and
step B of irradiating the amorphous semiconductor film with laser light a plurality of times through a mask having a plurality of openings while moving the substrate relative to the mask,
wherein step B includes a step of simultaneously forming a first molten region having a shape elongated in a first direction and a second molten region having a shape elongated in a second direction which is different from the first direction.

6. A laser annealing method comprising:
step A of preparing a substrate having an amorphous semiconductor film formed on a surface thereof; and
step B of forming a plurality of polycrystalline regions by irradiating the amorphous semiconductor film with laser light a plurality of times through a mask having a plurality of openings while moving the substrate relative to the mask so as to partially melt-crystallize the amorphous semiconductor film,
wherein the plurality of polycrystalline regions include a first polycrystalline region that has a shape elongated in a first direction and a second polycrystalline region that has a shape elongated in a second direction which is different from the first direction and step B includes a step of simultaneously forming a first molten region to be the first polycrystalline region and a second molten region to be the second polycrystalline region.

7. The laser annealing method of claim 6, wherein the first polycrystalline region and the second polycrystalline region are adjacent to each other.

8. The laser annealing method of claim 6, wherein
the second direction is perpendicular to the first direction, and the plurality of polycrystalline regions further include two third polycrystalline regions each of which is adjacent to the first polycrystalline region and has an elongated shape in the first direction, and
wherein step B includes, a step of simultaneously forming two third molten regions to be the two third polycrystalline regions.

9. The laser annealing method of claim 8, wherein step B includes, after forming the first polycrystalline region, a step of irradiating a region of the amorphous semiconductor film including the first polycrystalline region with the laser light so as to simultaneously form the two third molten regions to be the two third polycrystalline regions.

10. The laser annealing method of claim 6, wherein
the second direction is perpendicular to the first direction, and the plurality of polycrystalline regions further include two fourth polycrystalline regions each of which is adjacent to the second polycrystalline region and has an elongated shape in the second direction, and
wherein step B includes a step of simultaneously forming two fourth molten regions to be the two fourth polycrystalline regions.

11. A laser annealing method of claim 10, wherein step B includes, after forming the second polycrystalline region, a step of irradiating a region of the amorphous semiconductor film with the laser light which includes the second polycrystalline region so as to simultaneously form the two fourth molten regions to be the fourth polycrystalline regions.

12. A laser annealing method comprising:
step A of preparing a substrate having an amorphous semiconductor film formed on a surface thereof; and
step B of forming a plurality of polycrystalline regions by irradiating the amorphous semiconductor film with laser light a plurality of times through a mask having a plurality of openings while moving the substrate relative to the mask so as to partially melt-crystallize the amorphous semiconductor film,
wherein the plurality of polycrystalline regions include a first polycrystalline region that has a shape elongated in a first direction and a second polycrystalline region that is adjacent to the first polycrystalline region, and
step B includes a step of irradiating a molten region to be the second polycrystalline region with the laser light a plurality of times.

13. The laser annealing method of claim 12, wherein the substrate is moved relative to the mask in the first direction.

14. The laser annealing method of claim 12, wherein the substrate is moved relative to the mask in a direction perpendicular to the first direction.
